(19) United States
(12) Patent Application Publication
(10) Pub. No.: US 2025/0183119 A1
(43) Pub. Date: Jun. 5, 2025

(54) Underfill for Large Area Attaches for Semiconductor Packages

(71) Applicant: Wolfspeed, Inc., Durham, NC (US)

(72) Inventor: Sayan Seal, Fayetteville, AR (US)

(21) Appl. No.: 18/524,126

(22) Filed: Nov. 30, 2023

(51) Int. Cl. H01L 23/42; H01L 23/367; H01L 23/495

(52) U.S. Cl. CPC H01L 23/42; H01L 23/367; H01L 23/49517; H01L 23/49575

(57) ABSTRACT

Power semiconductor device assemblies are provided. In one example, a power semiconductor device assembly includes a semiconductor device package with one or more terminals. The semiconductor device package comprises one or more wide bandgap semiconductor die. The power semiconductor device assembly includes a support structure. The semiconductor device package is mounted onto the support structure. The power semiconductor device assembly includes an underfill structure. The underfill structure is at least partially on the support structure and the semiconductor device package.

### FIELD

Example aspects of the present disclosure relate generally to semiconductor devices.

### BACKGROUND

Semiconductor devices, including power semiconductor devices based on wide bandgap materials, may be formed on a semiconductor wafer as part of a semiconductor fabrication process. The semiconductor wafer may be diced into many individual pieces, each containing one or more semiconductor devices. Each of these pieces may be a semiconductor die. The semiconductor die may need to be attached to other components as part of packaging of the semiconductor device. For instance, a semiconductor die, such as a wide bandgap semiconductor die, may need to be attached to a conductive lead frame for use in a discrete power semiconductor device package or a power module. Materials used to attach the semiconductor die to other components may need to provide a thermal, mechanical, and/or electrical connection of the semiconductor die to the other components.

### SUMMARY

Aspects and advantages of embodiments of the present disclosure will be set forth in part in the following description, or can be learned from the description, or can be learned through practice of the embodiments.

One example aspect of the present disclosure is directed to a power semiconductor device assembly. The power semiconductor device assembly includes a semiconductor device package with one or more terminals. The semiconductor device package comprises one or more wide bandgap semiconductor die. The power semiconductor device assembly includes a support structure. The semiconductor device package is mounted onto the support structure. The power semiconductor device assembly includes an underfill structure. The underfill structure is at least partially on the support structure and the semiconductor device package.

Another example aspect of the present disclosure is directed to a power semiconductor device assembly. The power semiconductor device assembly includes a semiconductor device package with one or more terminals. The semiconductor device package includes one or more wide bandgap semiconductor die. The power semiconductor device assembly includes a support structure. The power semiconductor device assembly includes a patterned attach layer between the semiconductor device package and the support structure. The patterned attach layer comprises a plurality of attach structures. The patterned attach layer includes a gap between two or more of the attach structures.

Another example aspect of the present disclosure is directed to a method of forming a power semiconductor device assembly. The method includes providing a semiconductor device package with one or more terminals on a support structure. The semiconductor device package comprises one or more wide bandgap semiconductor die. The method includes providing an underfill structure at least partially on the semiconductor device package and the support structure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a cross-sectional view of an example power semiconductor device assembly as described in the present disclosure.

FIG. 2 depicts a cross-sectional view of an example power semiconductor device assembly according to example embodiments of the present disclosure.

FIG. 3 depicts a cross-sectional view of an example power semiconductor device assembly according to example embodiments of the present disclosure.

FIG. 4 depicts a cross-sectional view of an example power semiconductor device assembly according to example embodiments of the present disclosure.

FIG. 5 depicts a cross-sectional view of an example power semiconductor device assembly according to example embodiments of the present disclosure.

FIG. 6 depicts a cross-sectional view of an example power semiconductor device assembly according to example embodiments of the present disclosure.

FIG. 7 depicts a cross-sectional view of an example power semiconductor device assembly according to example embodiments of the present disclosure.

FIG. 8 depicts a cross-sectional view of an example power semiconductor device assembly according to example embodiments of the present disclosure.

FIG. 9 depicts a cross-sectional view of an example power semiconductor device assembly according to example embodiments of the present disclosure.

FIG. 10 depicts a flow chart diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to power semiconductor device assemblies including semiconductor device packages (e.g., discrete semiconductor device packages and power modules) mounted to support structures for use in semiconductor applications and other electronic applications. For example, the power semiconductor device assembly may include a semiconductor device package that is a power module. In some embodiments, semiconductor device packages may include one or more semiconductor die having at least one semiconductor device. For instance, the semiconductor die may include, for instance, wide bandgap semiconductor devices, such as silicon carbide-based semiconductor devices (e.g., MOSFETs, Schottky diodes), Group III nitride-based semiconductor devices (e.g., high electron mobility transistor (HEMT) devices, etc.). The semiconductor die may include a substrate, such as a wide bandgap substrate, such as a silicon carbide substrate. The semiconductor die may include an epitaxial layer on the substrate, such as a wide bandgap epitaxial layer, such as silicon carbide epitaxial layer and/or a Group III-nitride epitaxial layer.

In some power semiconductor device packages, one or more semiconductor device packages may be mounted on a support structure (e.g., a heat sink). According to examples of the present disclosure, the semiconductor device package may be mounted to the support structure with an underfill structure at least partially on the contact portion of the support structure and semiconductor device package. For instance, the semiconductor device package may be mounted to the support structure and the underfill structure may be an epoxy material on the support structure at least partially surrounding the semiconductor device package. The epoxy material may come up to and, at least partially, contact the semiconductor device package.

In some embodiments, one or more semiconductor device packages may be mounted on a support structure (e.g., support frame, heatsink, etc.) using an attach material such as, for example, sintered silver. More particularly, sintered silver (e.g., an attach material) may be deposited on the support structure, and the semiconductor device package may be placed on the attach material on the contact portion of the support structure. The attach material may be subjected to bonding or a bonding process (e.g., sintering) to secure the semiconductor device package to the attach material and support structure.

As used herein, the term “bonding” or “bonding process” refers to causing a transition of a material from a first form to a second form. A bonding process may or may not require attaching a component to the material. Sintering, reflow, annealing, curing, exposing to light, exposing to ultraviolet light, and ultrasonic bonding are examples of bonding processes and are encompassed by the term “bonding” or “bonding process” in the disclosure and in the claims.

The various technologies that are practiced in the semiconductor industry for mounting semiconductor device packages to support structures present specific challenges and limitations. For instance, the semiconductor device package and support structure may experience forces causing the contact portion between the two to separate and break. In mounting methods that require additional components, the additional components may deteriorate over time due to forces exerted on the additional components. Additionally, the semiconductor device package may experience continuous heat cycling throughout operation which may cause cracking or separation of the semiconductor device package from the support structure.

Example aspects of the present disclosure implement an underfill structure on a support structure to at least partially support a semiconductor device package on the support structure. The underfill structure may be on the support structure and, at least partially, on the semiconductor device package. For instance, the underfill structure may be on the support structure and may extend to a contact portion of the support structure and the semiconductor device package. In some embodiments, the underfill structure may extend to a height, at least partially, contacting the semiconductor device package. In some embodiments, the underfill structure may extend to and, at least partially, contact one or more terminals of the semiconductor device package. For example, the underfill structure may be a composite epoxy material disposed on a support structure and at least partially surrounding the semiconductor device package. The composite epoxy material may be on the support structure such that it congeals together and reaches the height of the terminals of the semiconductor device package.

The underfill structure may include a variety of chemical and physical properties that may improve durability and prevent degradation over time. As previously mentioned, the underfill structure may be an organic material, such as a composite epoxy material. In some embodiments, the underfill structure may include a material with a glass transition temperature between about 120° C. and 150° C. In some embodiments, the material may include a comparative tracking index greater than about 600. The material may also include a coefficient of thermal expansion. The coefficient of thermal expansion of the material may be less than a coefficient of thermal expansion of the support structure and greater than a coefficient of thermal expansion of the semiconductor device package. For example, the material may include a coefficient of thermal expansion between about 16 ppm/° C. and about 17 ppm/° C.

In some embodiments, the semiconductor device assembly includes an attach layer between the support structure and the semiconductor device package that bonds the semiconductor device package to the support structure. For example, the attach layer may include sintered silver and may be between the semiconductor device package and support structure. In some embodiments, the attach layer may be surrounded and, at least partially, contacted by an underfill structure. In some embodiments, the underfill structure may be on the attach layer. The underfill structure may at least partially surround the semiconductor device package and extend to a height up to and/or past the attach layer such that the underfill structure is, at least partially, on the attach layer.

In some embodiments, the attach layer may include a plurality of attach structures and two or more gaps between the attach structures. For example, the attach structures may be a plurality of attach structures in a grid pattern with two or more gaps separating the attach structures from each other. The plurality of attach structures may be on the support structure and the patterned attach layer may bond the support structure to the semiconductor device package.

Some example aspects of the present disclosure include a dam structure mounted on a support structure and at least partially surrounding the underfill structure. For example, the dam structure may surround the support structure and underfill structure. In some embodiments, the dam structure may include a dam height at least as high as a surface of the semiconductor device package. For example, the dam height may be as high as the a contact portion of the support structure and the semiconductor device package. In some embodiments, the dam height may be as high as, or extend past, one or more terminals of the semiconductor device package. The height of the underfill structure may be below or equal to the height of dam structure. In other words, the dam height may be equal to or greater than the height of the underfill structure. In some embodiments, the dam structure may be an epoxy material, and the epoxy material may have a viscosity less than a viscosity of the underfill structure. For example, the dam structure and the underfill structure may be epoxy materials but may include different viscosities. The dam structure epoxy material may have a lower viscosity than the underfill structure.

Some example aspects of the present disclosure are directed to a variety of semiconductor device packages and configurations. For instance, the semiconductor device package may be on a mesa of a support structure. The semiconductor device package may be on the mesa of the support structure such that the semiconductor device package overhangs the mesa. In some examples, the semiconductor device package does not overhang the mesa. In some embodiments, the semiconductor device package may include one or more terminals. The one or more terminals may protrude laterally from the semiconductor device package and may be connected to one or more semiconductor die within the semiconductor device package. For example, the one or more terminals may be connected to one or more wide bandgap semiconductor die. In some embodiments, the support structure may be a heatsink. The heatsink may dissipate heat from the semiconductor device package mounted thereon.

Aspects of the present disclosure provide a number of technical effects and benefits. For instance, an underfill structure in accordance with example aspects of the present disclosure may reduce or prevent a semiconductor device package from separating or breaking off from a support structure. The underfill structure may provide structural support to the electric terminals of the semiconductor device package and reduce stress within the semiconductor device package. Additionally, some example aspects of the present disclosure may improve the thermo-mechanical fatigue resistance of the semiconductor device package, support structure, and/or attach material. For example, an underfill structure may reinforce the semiconductor device package or support structure to reduce fatigue and prevent electrical or mechanical failure. Some aspects of the present disclosure may also provide creepage resistance between terminals of the semiconductor device package. Specifically, certain aspects of the present disclosure may prevent the creation of unintended conductive paths along isolator surfaces around the semiconductor device package. The creepage resistance may prevent arcing and short circuiting of the semiconductor device package.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

A wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

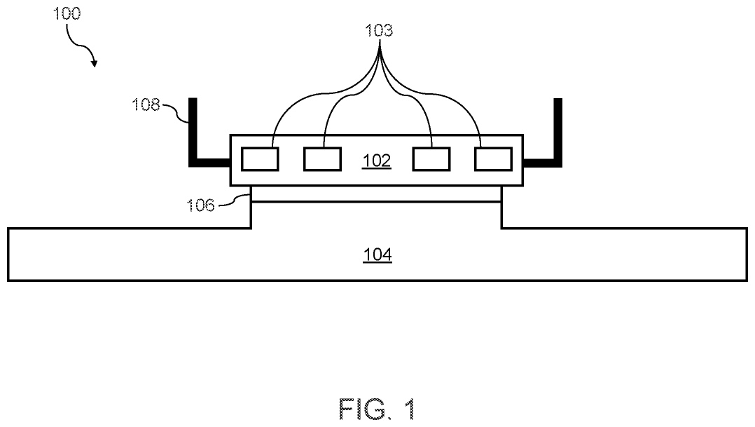

FIG. 1 depicts an example power semiconductor device assembly 100. The power semiconductor device assembly 100 may include a semiconductor device package 102 mounted on a support structure 104 using an attach layer 106. The semiconductor device package 102 may be mounted to the support structure 104. In some embodiments, the semiconductor device package 102 may include one or more terminals 108 that may protrude laterally from the semiconductor device package 102. Additionally, the semiconductor device package 102 may include one or more wide bandgap semiconductor die 103. In some embodiments, the power semiconductor device assembly may include an attach layer 106 such as, for example, sintered silver or other attach material. In some embodiments, the semiconductor device package 102 may be mounted on a mesa of the support structure 104. In some embodiments, the semiconductor device package 102 may overhang the mesa of the support structure 104.

The semiconductor device package 102 may include a variety of semiconductor die and devices. For instance, the semiconductor package 102 may include silicon-carbide based semiconductor die with one or more semiconductors devices such as a silicon carbide-based MOSFETs and/or silicon carbide-based Schottky diodes on the one or more wide bandgap semiconductor die 103. Additionally, or alternatively, the semiconductor device package 102 may include Group III nitride-based devices such as Group III nitride-based high electron mobility transistors (HEMTs) on the one or more wide bandgap semiconductor die 103. In some embodiments, the semiconductor device package 102 may be a power module. In some embodiments, the support structure 104 may be a heatsink that provides a cooling path thermal energy from the semiconductor device package 102.

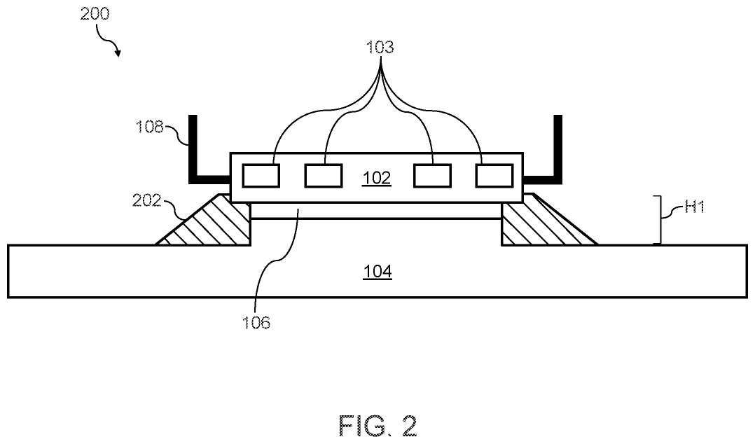

FIG. 2 depicts an example power semiconductor device assembly 200 according to example aspects of the present disclosure. The example power semiconductor device assembly 200 may include the semiconductor device package 102 mounted to the support structure 104 using an attach layer 106, as depicted in FIG. 1. Additionally, the power semiconductor device assembly 200 may also include the underfill structure 202. The underfill structure 202 may, at least partially, surround the semiconductor device package 102 and attach layer 106. In some embodiments, the underfill structure 202 may, at least partially, be on the attach layer 106. In some embodiments, the underfill structure 202 may, at least partially, contact the semiconductor device package 102. For example, the underfill structure 202 may be a composite epoxy material on the support structure 104 and surrounding the attach layer 106 and semiconductor device package 102 while at least partially contacting both.

The height of the underfill structure 202 may extend to a height H1 of the contact portion of the semiconductor device package 102 and the support structure 104. In some embodiments, the height of the underfill structure 202 may extend to a height of a surface of the semiconductor device package 102. For example, the underfill structure 202 may extend up to the base of the semiconductor device package 102 where it meets the attach layer 106 and may, at least partially, contact the semiconductor device package 102.

The underfill structure 202 may include a variety of chemical and physical properties for best use. For instance, the underfill structure 202 may include a material with a glass transition temperature in a range of about 120° C. to about 150° C. In some embodiments, the underfill structure 202 may include a material with a comparative tracking index greater than about 600. In some embodiments, the underfill structure 202 may include a material with a coefficient of thermal expansion in a range of about 16 ppm/° C. to about 17 ppm/° C. The underfill structure 202 may include a material with a coefficient of thermal expansion that is less than coefficient of thermal expansion of the support structure 104. In some embodiments, the coefficient of thermal expansion for the underfill structure 202 may be greater than a coefficient of thermal expansion associated with the semiconductor device package 102.

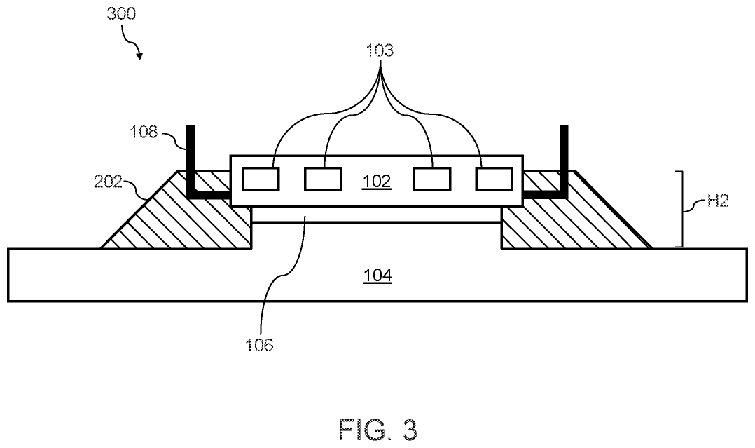

FIG. 3 depicts an example power semiconductor device assembly 300 according to example aspects of the present disclosure. The power semiconductor device assembly 300 may be similar to semiconductor device package 102 mounted on the support structure 104 using the attach layer 106 as depicted in FIGS. 1 & 2. The power semiconductor device assembly 300 may also include the underfill structure 302 surrounding the semiconductor device package 102 and attach layer 106. In some embodiments, the underfill structure 302 may extend to a height H2, at least, as high as the one or more terminals 108 of the semiconductor device package 102. In some embodiments, the underfill structure 302 may be, at least partially, contacting the semiconductor device package 102 and/or the one or more terminals 108. In this way, the underfill structure 302 may increase creepage (e.g., creepage resistance) between the one or more terminals 108.

The underfill structure 202 may include a variety of chemical and physical properties for best use. For instance, the underfill structure 202 may include a material with a glass transition temperature in a range of about 120° C. to about 150° C. In some embodiments, the underfill structure 202 may include a material with a comparative tracking index greater than about 600. In some embodiments, the underfill structure 202 may include a material with a coefficient of thermal expansion in a range of about 16 ppm/°° C. to about 17 ppm/° C. The underfill structure 202 may include a material with a coefficient of thermal expansion that is less than coefficient of thermal expansion of the support structure 104. In some embodiments, the coefficient of thermal expansion for the underfill structure 202 may be greater than a coefficient of thermal expansion associated with the semiconductor device package 102.

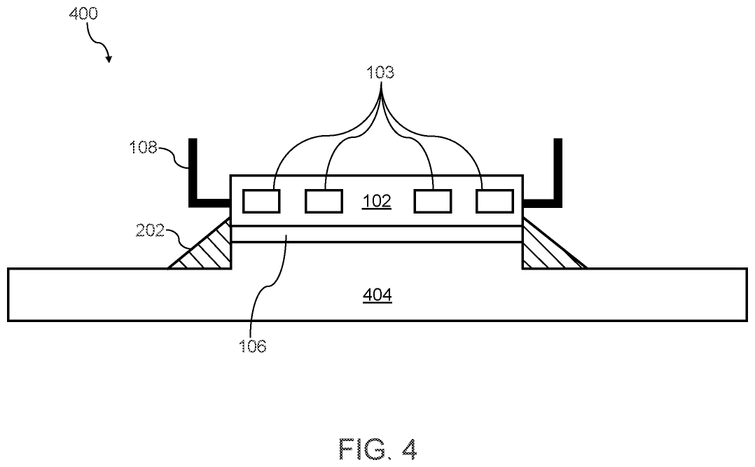

FIG. 4 depicts an example power semiconductor device assembly 400 according to aspects of the present disclosure. The power semiconductor device assembly 400 may be similar to the semiconductor device package 102, attach layer 106, and underfill structure 202 as depicted in FIG. 2. The power semiconductor device assembly 400 may also include a support structure 404 to which the power semiconductor package 102 is mounted with attach layer 106. As depicted, the support structure 404 may include a mesa. In some embodiments, the semiconductor device package 102 may be entirely contained on the mesa of the support structure 404. In other words, in some embodiments, the semiconductor device package 102 does not overhang the mesa of the support structure 404. In some embodiments, the support structure 404 may be a heatsink that provides a cooling path for thermal energy from the semiconductor device package 102.

The underfill structure 202 may include a variety of chemical and physical properties for best use. For instance, the underfill structure 202 may include a material with a glass transition temperature in a range of about 120° C. to about 150° C. In some embodiments, the underfill structure 202 may include a material with a comparative tracking index greater than about 600. In some embodiments, the underfill structure 202 may include a material with a coefficient of thermal expansion in a range of about 16 ppm/° C. to about 17 ppm/° C. The underfill structure 202 may include a material with a coefficient of thermal expansion that is less than coefficient of thermal expansion of the support structure 404. In some embodiments, the coefficient of thermal expansion for the underfill structure 202 may be greater than a coefficient of thermal expansion associated with the semiconductor device package 102.

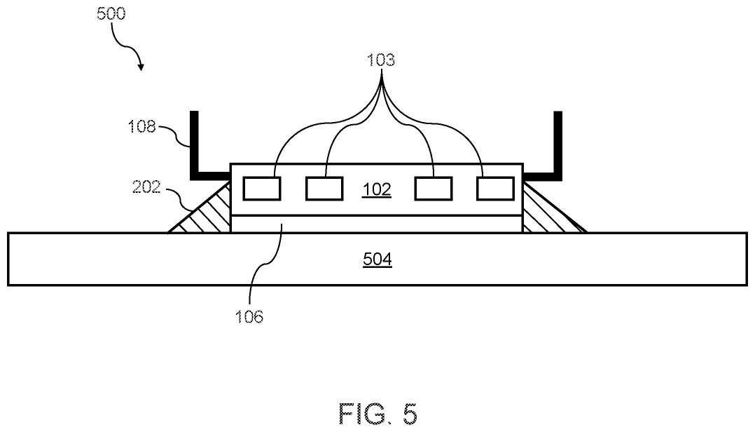

FIG. 5 depicts an example power semiconductor device assembly 500 according to aspects of the present disclosure. The power semiconductor device assembly 500 may include the semiconductor device package 102, attach layer 106, and underfill structure 202 as depicted in FIG. 2. The power semiconductor device assembly 500 may also include a support structure 504. The attach layer 106 may be directly on the support structure 504 and the semiconductor device package 102 may be mounted to the support structure 504 via the attach layer 106. For instance, the attach layer 106 may be placed on a flat surface of the support structure 504 and the semiconductor device package 102 may be mounted to the support structure 504 via the attach layer 106. In some embodiments, the support structure 504 may be a heatsink that radiates thermal energy from the semiconductor device package 102.

The underfill structure 202 may include a variety of chemical and physical properties for best use. For instance, the underfill structure 202 may include a material with a glass transition temperature in a range of about 120° C. to about 150° C. In some embodiments, the underfill structure 202 may include a material with a comparative tracking index greater than about 600. In some embodiments, the underfill structure 202 may include a material with a coefficient of thermal expansion in a range of about 16 ppm/° C. to about 17 ppm/° C. The underfill structure 202 may include a material with a coefficient of thermal expansion that is less than coefficient of thermal expansion of the support structure 504. In some embodiments, the coefficient of thermal expansion for the underfill structure 202 may be greater than a coefficient of thermal expansion associated with the semiconductor device package 102.

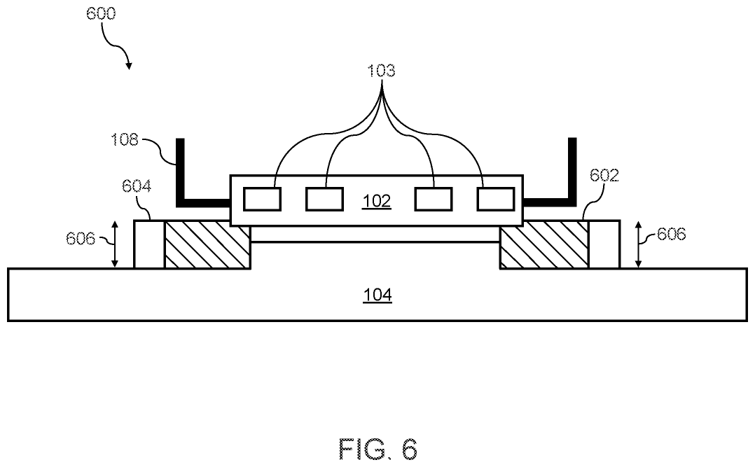

FIG. 6 depicts an example power semiconductor device assembly 600 according to aspects of the present disclosure. The power semiconductor device assembly 600 may be similar to the power semiconductor device assembly 100 as depicted in FIG. 1. The power semiconductor device assembly 600 may also include an underfill structure 602 and dam structure 604 with a dam height 606. The dam structure 604 and underfill structure 602 may, at least partially, surround the semiconductor device package 102 and attach layer 106. The underfill structure 602 may be, at least partially, contacting the semiconductor device package 102 and the dam structure 604. The dam structure 604 may act as a container for the underfill structure 602 and help maintain the form of the underfill structure 602. For example, the dam structure 604 may be an epoxy material with a viscosity less than a viscosity of the underfill structure 602. The dam structure 604 may contain the underfill structure 602. In some embodiments, the dam structure 604 may have a dam height 606 that extends to a surface of the semiconductor device package 102. For example, the dam height 606 may extend to the base of the semiconductor device package 102 that contacts the attach layer 106. In some embodiments, the height of the underfill structure 602 is equal to the dam height 606 of the dam structure 604.

The underfill structure 602 may include a variety of chemical and physical properties for best use. For instance, the underfill structure 602 may include a material with a glass transition temperature in a range of about 120° C. to about 150° C. In some embodiments, the underfill structure 602 may include a material with a comparative tracking index greater than about 600. In some embodiments, the underfill structure 602 may include a material with a coefficient of thermal expansion in a range of about 16 ppm/° C. to about 17 ppm/° C. The underfill structure 602 may include a material with a coefficient of thermal expansion that is less than coefficient of thermal expansion of the support structure 104. In some embodiments, the coefficient of thermal expansion for the underfill structure 602 may be greater than a coefficient of thermal expansion associated with the semiconductor device package 102.

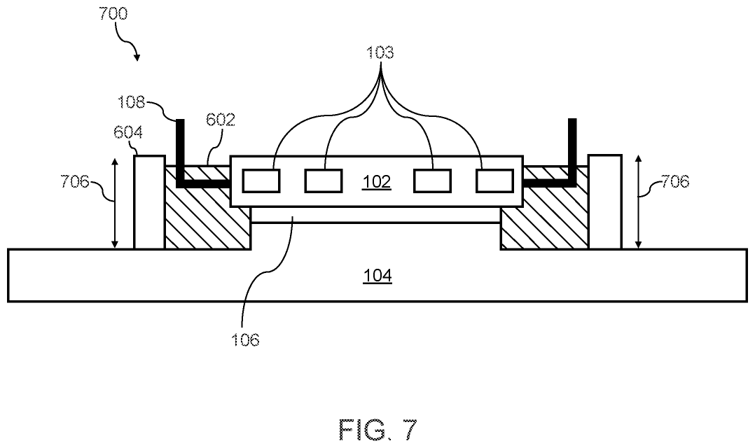

FIG. 7 depicts an example power semiconductor device assembly 700 according to example aspects of the present disclosure. The power semiconductor device assembly 700 may be similar to the power semiconductor device assembly 600 as depicted in FIG. 6. The power semiconductor device assembly 700 may include dam structure having a dam height of 706. In some embodiments, the dam height 706 may extend, at least, to the one or more terminals 108 of the semiconductor device package 102. Additionally, the height of the underfill structure 602 may also extend to, at least, the height of the one or more terminals 108 of the semiconductor device package 102. The underfill structure 602 may, at least partially, be contacting the one or more terminals 108. In some embodiments, the dam height 706 may be greater than the height of the underfill structure 602.

The underfill structure 602 may include a variety of chemical and physical properties for best use. For instance, the underfill structure 602 may include a material with a glass transition temperature in a range of about 120° C. to about 150° C. In some embodiments, the underfill structure 602 may include a material with a comparative tracking index greater than about 600. In some embodiments, the underfill structure 602 may include a material with a coefficient of thermal expansion in a range of about 16 ppm/° C. to about 17 ppm/° C. The underfill structure 602 may include a material with a coefficient of thermal expansion that is less than coefficient of thermal expansion of the support structure 104. In some embodiments, the coefficient of thermal expansion for the underfill structure 602 may be greater than a coefficient of thermal expansion associated with the semiconductor device package 102.

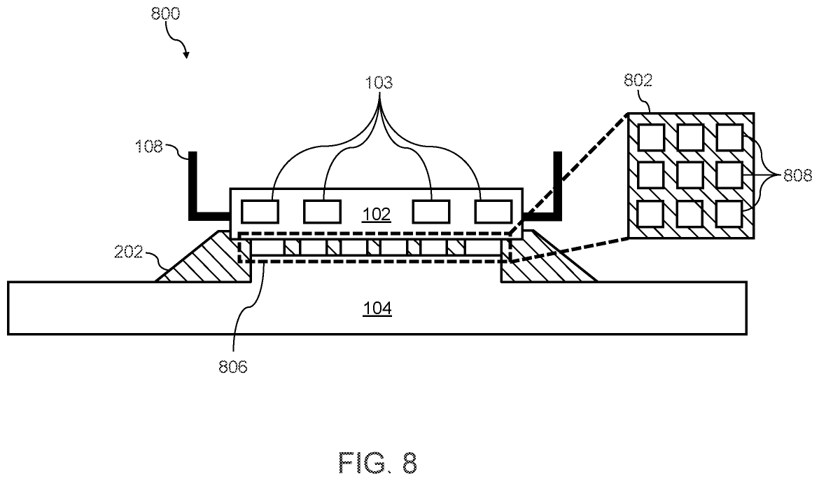

FIG. 8 depicts an example power semiconductor device assembly 800 according to example aspects of the present disclosure. The power semiconductor device assembly 800 may be similar to the power semiconductor device assembly 200 as depicted in FIG. 2. The power semiconductor device assembly 800 may also include an attach layer 806 including one or more attach structures 808. The attach layer 806 may have two or more gaps within it that separate the one or more attach structures 808. In some embodiments, the one or more attach structures 808 may be formed in a pattern. For example, the one or more attach structures 808 may be formed in a grid pattern (e.g., an array of rows and columns of attach structures 808) with two or more gaps separating the attach structures 808. In some embodiments, the underfill structure 202 may fill the two or more gaps in the attach layer 806 that separate the one or more attach structures 808. For instance, the one or more attach structures 808 may be in a grid pattern with the underfill structure 202 filling the gaps between the one or more attach structures 808 in the grid pattern of the patterned attach layer 806.

FIG. 8 depicts one example pattern for attach structures 808 for purposes of illustration and discussion. Those of ordinary skill in the art, using the disclosures provided herein, will understand that other suitable patterns may be used without deviating from the scope of the present disclosure. For instance, the pattern may be a square tile pattern, herringbone pattern, pattern of hexagonal attach structures, pattern of triangular attach structures, or other suitable pattern.

The underfill structure 202 may include a variety of chemical and physical properties for best use. For instance, the underfill structure 202 may include a material with a glass transition temperature in a range of about 120° C. to about 150° C. In some embodiments, the underfill structure 202 may include a material with a comparative tracking index greater than about 600. In some embodiments, the underfill structure 202 may include a material with a coefficient of thermal expansion in a range of about 16 ppm/° C. to about 17 ppm/° C. The underfill structure 202 may include a material with a coefficient of thermal expansion that is less than coefficient of thermal expansion of the support structure 104. In some embodiments, the coefficient of thermal expansion for the underfill structure 202 may be greater than a coefficient of thermal expansion associated with the semiconductor device package 102.

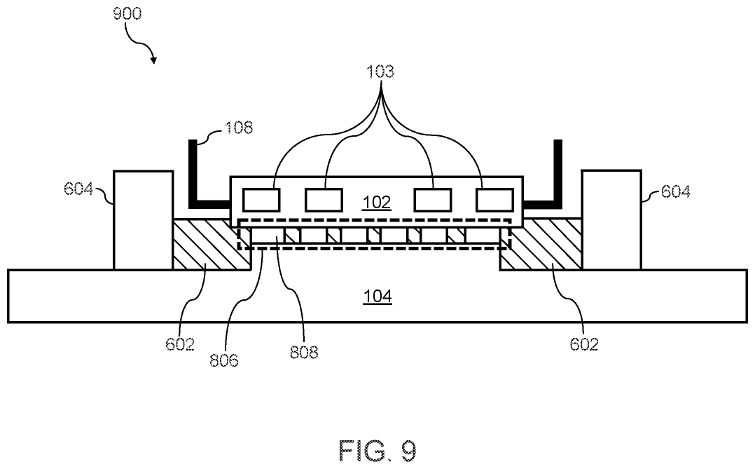

FIG. 9 depicts an example power semiconductor device assembly 900 according to example embodiments of the present disclosure. The power semiconductor device assembly 900 may be similar to the power semiconductor device assembly 600 as depicted in FIG. 6. The power semiconductor assembly 900 may also include the attach layer 806 and the one or more attach structures 808 as depicted in FIG. 8. The attach layer 806 may include one or more attach structures 808 that bond the semiconductor device package 102 to the support structure 104. In some embodiments, the one or more attach structures 808 may be formed in a pattern with two or more gaps between the one or more attach structures 808 forming a patterned attach layer 806.

In some embodiments, a dam structure 604 may surround the underfill structure 602 and maintain the shape of the underfill structure 602. In some embodiments, the underfill structure 602 may surround the semiconductor device package 102 and may fill the two or more gaps that separate the one or more attach structures 808 of the attach layer 806.

The underfill structure 602 may include a variety of chemical and physical properties for best use. For instance, the underfill structure 602 may include a material with a glass transition temperature in a range of about 120° C. to about 150° C. In some embodiments, the underfill structure 602 may include a material with a comparative tracking index greater than about 600. In some embodiments, the underfill structure 602 may include a material with a coefficient of thermal expansion in a range of about 16 ppm/° C. to about 17 ppm/° C. The underfill structure 602 may include a material with a coefficient of thermal expansion that is less than coefficient of thermal expansion of the support structure 104. In some embodiments, the coefficient of thermal expansion for the underfill structure 602 may be greater than a coefficient of thermal expansion associated with the semiconductor device package 102.

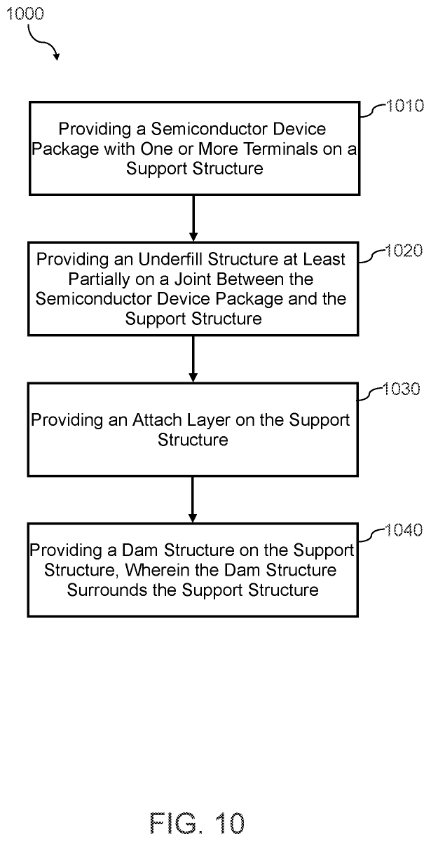

FIG. 10 depicts an example method 1000 of providing a semiconductor device package according to example aspects of the present disclosure. FIG. 10 depicts operations performed in a particular order for purposes of illustration and discussion. Those of ordinary skill in the art, using the disclosures provided herein, will understand that various operations of any of the methods described herein can be adapted, expanded, omitted, rearranged, include steps or operations not illustrated, and/or modified in various ways without deviating from the scope of the present disclosure.

At 1010, the method includes providing a semiconductor device package with one or more terminals on a support structure. The semiconductor device package may be mounted on a mesa of the support structure and may overhang the mesa. In some embodiments, the semiconductor device package may be mounted on a mesa of the support structure and does not overhang the mesa. In some embodiments, the semiconductor device package may be mounted to a flat surface of the support structure. In some embodiments, the support structure may be a heatsink that provides a cooling path thermal energy from the semiconductor device package.

The semiconductor device package may include a variety of configurations. For instance, the semiconductor device package may include one or more terminals that protrude laterally from the semiconductor device package. The one or more terminals may be connected to one or more wide bandgap semiconductor die. In some embodiments, the semiconductor device package may include one or more wide bandgap semiconductor die. In some embodiments, the semiconductor device package may include silicon carbide-based semiconductor devices such as, for example, a silicon carbide-based MOSFET or a silicon carbide-based Schottky diode. Additionally, or alternatively, the semiconductor device package may include Group III nitride-based semiconductor die and devices such as, for example, HEMTs. In some embodiments, the semiconductor device package may be a power module.

At 1020, the method includes providing an underfill structure at least partially on a joint between the semiconductor device package and the support structure. The underfill structure may include a composite epoxy material and may extend to a height, at least partially, contacting the semiconductor device package. In some embodiments, the underfill structure may be on the support structure and extend to a height, at least partially, contacting the one or more terminals of the semiconductor device package.

The underfill structure may include a variety of chemical and physical properties for best use. For instance, the underfill structure may include a material with a glass transition temperature in a range of about 120° C. to about 150° C. In some embodiments, the underfill structure may include a material with a comparative tracking index greater than about 600. In some embodiments, the underfill structure may include a material with a coefficient of thermal expansion in a range of about 16 ppm/° C. to about 17 ppm/° C. The underfill structure may include a material with a coefficient of thermal expansion that is less than coefficient of thermal expansion of the support structure. In some embodiments, the coefficient of thermal expansion for the underfill structure may be greater than a coefficient of thermal expansion associated with the semiconductor device package.

At 1030, the method includes providing an attach layer on the support structure. For instance, the attach layer may be sintered silver and applied to the support structure to mount the semiconductor device package on the support structure. The attach layer may be surrounded by the underfill structure and the underfill structure may, at least partially, contact the attach layer. In some embodiments, the attach layer may include a plurality of attach structures with two or more gaps between the attach structures. In one embodiment, the plurality of attach structures may be in a grid pattern. For example, the plurality of attach structures may form a square grid with two or more gaps between the plurality of attach structures forming the lines of the grid. In some embodiments, the underfill structure may fill the two or more gaps between the plurality of attach structures in the grid of the patterned attach layer.

At 1040, the method includes providing a dam structure on the support structure, and the dam structure surrounds the support structure. The dam structure may surround the underfill structure on the support structure. In some embodiments, the dam structure may have a dam height that extends, at least, to a surface of the semiconductor device package. In another embodiment, the dam height may extend, at least, to the one or more terminals of the semiconductor device package. In some embodiments, the dam height may be equal to the height of the underfill structure. In some embodiments, the dam height may be greater than the height of the underfill structure.

The dam structure may be a material that contains the underfill structure. For instance, the dam structure may be an epoxy material, and the epoxy material may have a viscosity that is less than a viscosity of the underfill structure.

Example aspects of the present disclosure are set forth below. Any of the below features or examples may be used in combination with any of the embodiments or features provided in the present disclosure.

One example aspect of the present disclosure is directed to a power semiconductor device assembly. The power semiconductor device assembly includes a semiconductor device package with one or more terminals. The semiconductor device package comprises one or more wide bandgap semiconductor die. The power semiconductor device assembly includes a support structure. The semiconductor device package is mounted onto the support structure. The power semiconductor device assembly includes an underfill structure. The underfill structure is at least partially on the support structure and the semiconductor device package.

In some embodiments, the underfill structure is on the support structure and extends to a height at least partially contacting the semiconductor device package. In some embodiments, the underfill structure is on the support structure and extends to a height at least partially contacting the one or more terminals. In some embodiments, the underfill structure at least partially surrounds a portion of the semiconductor device package.

In some embodiments, the underfill structure is a composite epoxy material. In some embodiments, the underfill structure comprises a material having a glass transition temperature in a range of about 120° C. to about 150° C. In some embodiments, the underfill structure comprises a material having a comparative tracking index greater than about 600.

In some embodiments, the underfill structure comprises a material having a first coefficient of thermal expansion that is less than a second coefficient of thermal expansion of the support structure. In some embodiments, the first coefficient of thermal expansion is greater than a third coefficient of thermal expansion associated with the semiconductor device package. In some embodiments, the underfill structure comprises a material having a coefficient of thermal expansion in a range of about 16 ppm/° C. to about 17 ppm/° C.

In some embodiments, the power semiconductor device assembly further comprises an attach layer between the semiconductor device package and the support structure. In some embodiments, the attach layer comprises sintered silver. In some embodiments, the underfill structure is on the attach layer. In some embodiments, the underfill structure at least partially surrounds the attach layer.

In some embodiments, the attach layer comprises a plurality of attach structures, the attach layer comprising a gap between two or more of the attach structures. In some embodiments, the plurality of attach structures are arranged in a grid pattern. In some embodiments, the underfill structure at least partially fills the gap between two or more of the attach structures.

In some embodiments, the power semiconductor device assembly includes a dam structure. The dam structure is on the support structure and at least partially surrounds the underfill structure. In some embodiments, the dam structure has a dam height extending at least to a surface of the semiconductor device package. In some embodiments, the dam height extends at least to the one or more terminals of the semiconductor device package. In some embodiments, the dam height is at least equal to a height of the underfill structure. In some embodiments, the dam height is greater than the height of the underfill structure.

In some embodiments, the dam structure is an epoxy material. In some embodiments, the epoxy material has a viscosity that is less than a viscosity of the underfill structure.

In some embodiments, the support structure is a heatsink. In some embodiments, the semiconductor device package is on a mesa of the support structure. In some embodiments, the semiconductor device package overhangs the mesa. In some embodiments, the semiconductor device package does not overhang the mesa.

In some embodiments, the one or more terminals protrude laterally from the semiconductor device package and are connected to the one or more wide bandgap semiconductor die.

In some embodiments, the one or more wide bandgap semiconductor die comprise silicon carbide. In some embodiments, the semiconductor device package comprises a silicon carbide-based MOSFET. In some embodiments, the semiconductor device package comprises a silicon carbide-based Schottky diode. In some embodiments, the one or more wide bandgap semiconductor die comprise a Group III-nitride. In some embodiments, the semiconductor device package comprises a Group III nitride-based high electron mobility transistor.

In some embodiments, the semiconductor device package is a power module.

Another example aspect of the present disclosure is directed to a power semiconductor device assembly. The power semiconductor device assembly includes a semiconductor device package with one or more terminals. The semiconductor device package includes one or more wide bandgap semiconductor die. The power semiconductor device assembly includes a support structure. The power semiconductor device assembly includes a patterned attach layer between the semiconductor device package and the support structure. The patterned attach layer comprises a plurality of attach structures. The patterned attach layer includes a gap between two or more of the attach structures.

In some embodiments, the patterned attach layer comprises sintered silver. In some embodiments, the plurality of attach structures are arranged in a grid pattern.

In some embodiments, the power semiconductor device assembly includes an underfill structure disposed on the support structure. The underfill structure is at least partially on the semiconductor device package. In some embodiments, the underfill structure at least partially fills the gap between two or more of the attach structures.

In some embodiments, the underfill structure is on the support structure and extends to a height at least partially contacting the semiconductor device package. In some embodiments, the underfill structure is on the support structure and extends to a height at least partially contacting the one or more terminals.

In some embodiments, the underfill structure is a composite epoxy material. In some embodiments, the underfill structure at least partially surrounds a portion of the semiconductor device package. In some embodiments, the underfill structure comprises a material having a glass transition temperature in a range of about 120° C. to about 150° C. In some embodiments, the underfill structure comprises a material having a comparative tracking index greater than about 600.

In some embodiments, the underfill structure comprises a material having a first coefficient of thermal expansion that is less than a second coefficient of thermal expansion of the support structure. In some embodiments, the first coefficient of thermal expansion is greater than a third coefficient of thermal expansion associated with the semiconductor device package. In some embodiments, the underfill structure comprises a material having a coefficient of thermal expansion in a range of about 16 ppm/° C. to about 17 ppm/° C.

In some embodiments, the underfill structure is on the patterned attach layer. In some embodiments, the underfill structure at least partially surrounds the patterned attach layer.

In some embodiments, the power semiconductor device assembly includes a dam structure. The dam structure is on the support structure and at least partially surrounds the underfill structure. In some embodiments, the dam structure has a dam height extending at least to a surface of the semiconductor device package. In some embodiments, the dam height extends at least to the one or more terminals of the semiconductor device package. In some embodiments, the dam height is at least equal to a height of the underfill structure. In some embodiments, the dam height is greater than the height of the underfill structure.

In some embodiments, the dam structure is an epoxy material. In some embodiments, the epoxy material has a viscosity that is less than a viscosity of the underfill structure.

In some embodiments, the support structure is a heatsink. In some embodiments, the semiconductor device package is on a mesa of the support structure. In some embodiments, the semiconductor device package overhangs the mesa. In some embodiments, the semiconductor device package does not overhang the mesa.

In some embodiments, the one or more terminals protrude laterally from the semiconductor device package and are connected to the one or more wide bandgap semiconductor die.

In some embodiments, the one or more wide bandgap semiconductor die comprise silicon carbide. In some embodiments, the semiconductor device package comprises a silicon carbide-based MOSFET. In some embodiments, the semiconductor device package comprises a silicon carbide-based Schottky diode. In some embodiments, the one or more wide bandgap semiconductor die comprise a Group III-nitride. In some embodiments, the semiconductor device package comprises a Group III nitride-based high electron mobility transistor.

In some embodiments, the semiconductor device package is a power module.

Another example aspect of the present disclosure is directed to a method of forming a power semiconductor device assembly. The method includes providing a semiconductor device package with one or more terminals on a support structure. The semiconductor device package comprises one or more wide bandgap semiconductor die. The method includes providing an underfill structure at least partially on the semiconductor device package and the support structure.

In some embodiments, the underfill structure is on the support structure and extends to a height at least partially contacting the semiconductor device package. In some embodiments, the underfill structure is on the support structure and extends to a height at least partially contacting the one or more terminals. In some embodiments, the underfill structure at least partially surrounds a portion of the semiconductor device package.

In some embodiments, the underfill structure is a composite epoxy material. In some embodiments, the underfill structure comprises a material having a glass transition temperature in a range of about 120° C. to about 150° C. In some embodiments, the underfill structure comprises a material having a comparative tracking index greater than about 600.

In some embodiments, the underfill structure comprises a material having a first coefficient of thermal expansion that is less than a second coefficient of thermal expansion of the support structure. In some embodiments, the first coefficient of thermal expansion is greater than a third coefficient of thermal expansion associated with the semiconductor device package. In some embodiments, the underfill structure comprises a material having a coefficient of thermal expansion in a range of about 16 ppm/° C. to about 17 ppm/° C.

In some embodiments, the power semiconductor device assembly further comprises an attach layer between the semiconductor device package and the support structure. In some embodiments, the attach layer comprises sintered silver. In some embodiments, the underfill structure is on the attach layer. In some embodiments, the underfill structure at least partially surrounds the attach layer.

In some embodiments, the attach layer comprises a plurality of attach structures, the attach layer comprising a gap between two or more of the attach structures. In some embodiments, the plurality of attach structures are arranged in a grid pattern. In some embodiments, the underfill structure at least partially fills the gap between two or more of the attach structures.

In some embodiments, the power semiconductor device assembly includes a dam structure. The dam structure is on the support structure and at least partially surrounds the underfill structure. In some embodiments, the dam structure has a dam height extending at least to a surface of the semiconductor device package. In some embodiments, the dam height extends at least to the one or more terminals of the semiconductor device package. In some embodiments, the dam height is at least equal to a height of the underfill structure. In some embodiments, the dam height is greater than the height of the underfill structure.

In some embodiments, the dam structure is an epoxy material. In some embodiments, the epoxy material has a viscosity that is less than a viscosity of the underfill structure.

In some embodiments, the support structure is a heatsink. In some embodiments, the semiconductor device package is on a mesa of the support structure. In some embodiments, the semiconductor device package overhangs the mesa. In some embodiments, the semiconductor device package does not overhang the mesa.

In some embodiments, the one or more terminals protrude laterally from the semiconductor device package and are connected to the one or more wide bandgap semiconductor die.

In some embodiments, the one or more wide bandgap semiconductor die comprise silicon carbide. In some embodiments, the semiconductor device package comprises a silicon carbide-based MOSFET. In some embodiments, the semiconductor device package comprises a silicon carbide-based Schottky diode. In some embodiments, the one or more wide bandgap semiconductor die comprise a Group III-nitride. In some embodiments, the semiconductor device package comprises a Group III nitride-based high electron mobility transistor.

In some embodiments, the semiconductor device package is a power module.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A power semiconductor device assembly comprising:
a semiconductor device package with one or more terminals, wherein the semiconductor device package comprises one or more wide bandgap semiconductor die;
a support structure, wherein the semiconductor device package is mounted onto the support structure; and
an underfill structure, wherein the underfill structure is at least partially on the support structure and the semiconductor device package.

2. The power semiconductor device assembly of claim 1, wherein the underfill structure is on the support structure and extends to a height at least partially contacting the semiconductor device package.

3. The power semiconductor device assembly of claim 1, wherein the underfill structure is on the support structure and extends to a height at least partially contacting the one or more terminals.

4. The power semiconductor device assembly of claim 1, wherein the underfill structure is a composite epoxy material.

5. (canceled)

6. The power semiconductor device assembly of claim 1, wherein the underfill structure comprises a material having a glass transition temperature in a range of about 120° C. to about 150° C.

7. The power semiconductor device assembly of claim 1, wherein the underfill structure comprises a material having a comparative tracking index greater than about 600.

8. The power semiconductor device assembly of claim 1, wherein the underfill structure comprises a material having a first coefficient of thermal expansion that is less than a second coefficient of thermal expansion of the support structure, wherein the first coefficient of thermal expansion is greater than a third coefficient of thermal expansion associated with the semiconductor device package.

9. (canceled)

10. The power semiconductor device assembly of claim 1, wherein the underfill structure comprises a material having a coefficient of thermal expansion in a range of about 16 ppm/° C. to about 17 ppm/° C.

11. The power semiconductor device assembly of claim 1, wherein the power semiconductor device assembly further comprises an attach layer between the semiconductor device package and the support structure, wherein the underfill structure is on the attach layer.

12.-14. (canceled)

15. The power semiconductor device assembly of claim 11, wherein the attach layer comprises a plurality of attach structures, the attach layer comprising a gap between two or more of the attach structures.

16. (canceled)

17. The power semiconductor device assembly of claim 15, wherein the underfill structure at least partially fills the gap between two or more of the attach structures.

18. The power semiconductor device assembly of claim 1, further comprising:
a dam structure, wherein the dam structure is on the support structure and at least partially surrounds the underfill structure.

19.-22. (canceled)

23. The power semiconductor device assembly of claim 18, wherein the dam structure is an epoxy material, wherein the epoxy material has a viscosity that is less than a viscosity of the underfill structure.

24. (canceled)

25. The power semiconductor device assembly of claim 1, wherein the support structure is a heatsink.

26. The power semiconductor device assembly of claim 1, wherein the semiconductor device package is on a mesa of the support structure.

27.-29. (canceled)

30. The power semiconductor device assembly of claim 1, wherein the one or more wide bandgap semiconductor die comprise silicon carbide, wherein the semiconductor device package comprises a silicon carbide-based MOSFET or a silicon carbide-based Schottky diode.

31.-32. (canceled)

33. The power semiconductor device assembly of claim 1, wherein the one or more wide bandgap semiconductor die comprise a Group III-nitride, wherein the semiconductor device package comprises a Group III nitride-based high electron mobility transistor.

34. (canceled)

35. The power semiconductor device assembly of claim 1, wherein the semiconductor device package is a power module.

36. A power semiconductor device assembly comprising:
a semiconductor device package with one or more terminals, wherein the semiconductor device package comprises one or more wide bandgap semiconductor die;
a support structure; and
a patterned attach layer between the semiconductor device package and the support structure, wherein the patterned attach layer comprises a plurality of attach structures, the patterned attach layer comprising a gap between two or more of the attach structures.

37.-69. (canceled)

70. A method of forming a power semiconductor device assembly, the method comprising:
providing a semiconductor device package with one or more terminals on a support structure, wherein the semiconductor device package comprises one or more wide bandgap semiconductor die; and
providing an underfill structure at least partially on the semiconductor device package and the support structure.

71.-103. (canceled)
